(19) United States
(12) Patent Application Publication
(10) Pub. No.: US 2026/0068490 A1
(43) Pub. Date: Mar. 5, 2026

(54) DISPLAY DEVICE

(71) Applicant: Samsung Display Co., LTD., Yongin-si (KR)

(72) Inventor: Ho LIM, Yongin-si (KR)

(21) Appl. No.: 19/094,881

(22) Filed: Mar. 29, 2025

(30) Foreign Application Priority Data
Aug. 27, 2024 (KR) 10-2024-0115120

(51) Int. Cl. H10K 59/80; H10K 59/38; H10K 59/40; H10K 102/00

(52) U.S. Cl. CPC H10K 59/873; H10K 59/38; H10K 59/40; H10K 59/877; H10K 2102/331; H10K 2102/351

(57) ABSTRACT

A display device includes a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer, wherein the overcoat layer includes a base resin and a moisture-absorbing agent dispersed in the base resin.

This application claims priority to Korean Patent Application No. 10-2024-0115120, filed on Aug. 27, 2024, and all the benefits accruing therefrom under 35 U.S.C. § 119, the content of which in its entirety is herein incorporated by reference.

### BACKGROUND

### 1. Field

The invention relates generally to a display device, and more particularly to a display device that can improve defects in color filters caused by moisture.

### 2. Description of the Related Art

As the information society develops, the demand for display devices for displaying images is increasing in various forms. For example, display devices are being applied to various electronic devices such as smartphones, digital cameras, laptop computers, navigation systems, and smart televisions (TVs).

The display devices may be flat panel display devices such as liquid crystal display (LCD) devices, field-emission display (FED) devices, or light-emitting display devices. The light-emitting display devices include organic light-emitting display devices that contain organic light-emitting elements, inorganic light-emitting display devices that contain inorganic light-emitting elements such as inorganic semiconductors, and micro light-emitting display devices that contain micro light-emitting elements.

The organic light-emitting elements may each include two opposing electrodes and a light-emitting layer interposed between the two opposing electrodes. The light-emitting layer receives electrons and holes from the two electrodes and recombines the electrons and holes to generate excitons. The excitons transition from an excited to a ground state thereby emitting light.

Since organic light-emitting display devices including organic light-emitting elements do not require light sources such as backlight units, they have low power consumption, can be constructed in a thin and lightweight form, and can offer high-quality characteristics such as a wide viewing angle, high brightness, high contrast, and fast response speed, recognized as next-generation display devices.

### SUMMARY

Aspects of the invention provide a display device that can improve defects in color filters caused by moisture.

However, aspects of the invention are not restricted to those set forth herein. The above and other aspects will become more apparent to one of ordinary skill in the art to which the invention pertains by referencing the detailed description of the present disclosure given below.

According to an aspect, a display device includes a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer, wherein the overcoat layer includes a base resin and a moisture-absorbing agent dispersed in the base resin.

In an embodiment, a modulus of the overcoat layer is in the range of about 3 GPa to about 60 GPa.

In an embodiment, the base resin includes at least one of Chemical Formulas A, B, D, and E, shown immediately below:

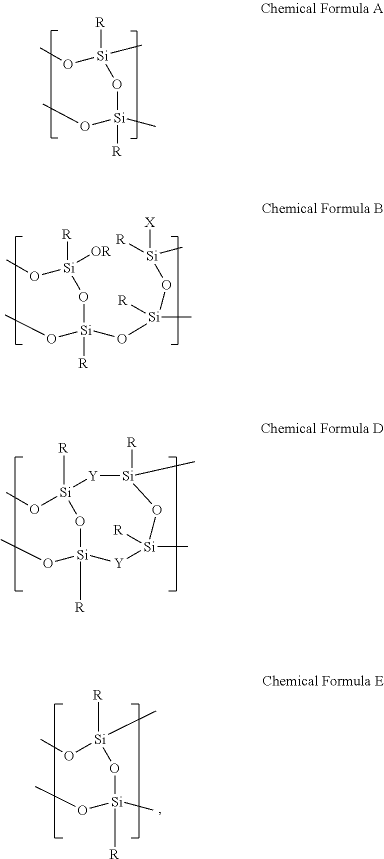

and wherein in Chemical Formula B or D, X and Y are each independently R or [(SiO_{3/2}R)₄₊₂ₙO] (where n is 1 to 10), and wherein R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms, wherein the phenyl group is either substituted with a substituent or unsubstituted and wherein the substituent is selected from hydrogen, deuterium, halogen, an amino group, an epoxy group, a cyclohexyl epoxy group, an acryl group, a methacryl group, a thiol group, an isocyanate group, a nitrile group, or a nitro group.

In an embodiment, the base resin includes at least one compound selected from Chemical Formulas 1 through 14, wherein Chemical Formulas 1 through 9 are as follows:

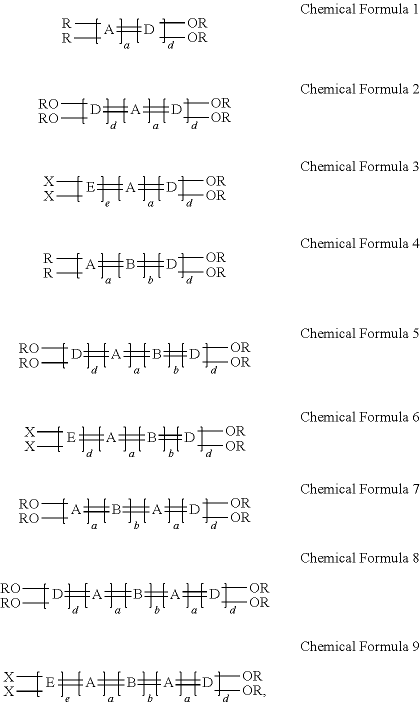

where in Chemical Formulas 1 through 9, R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms, wherein the phenyl group is either substituted with a substituent or unsubstituted, the substituent is independently selected from hydrogen, deuterium, halogen, an amino group, an epoxy group, a cyclohexyl epoxy group, an acryl group, a methacryl group, a thiol group, an isocyanate group, a nitrile group, and a nitro group, X is independently selected from R or [(SiO_{3/2}R)₄₊₂ₙO] (where n is 1 to 10) and a, b, d, and e are integers from 1 to 1000, Chemical Formulas 10 through 14 are as follows:

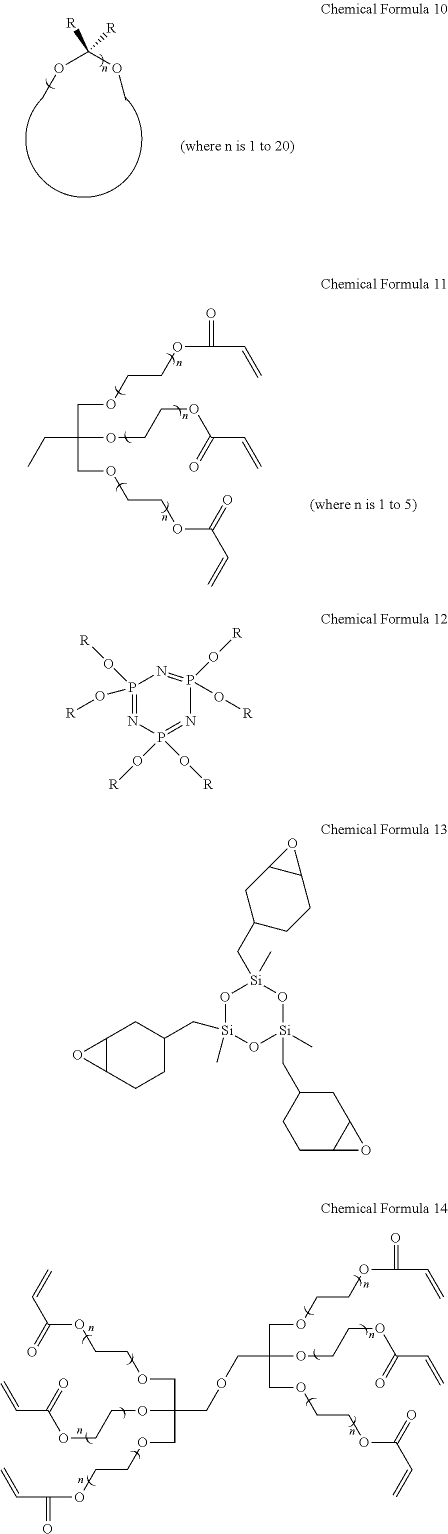

and where in Chemical Formulas 10 and 12, R is selected from

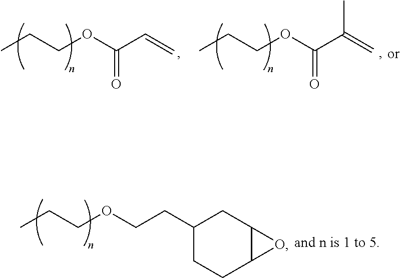

In an embodiment, the moisture-absorbing agent includes at least one inorganic moisture-absorbing agent selected from zeolite, porous silica, metal-organic frameworks (MOFs), alumina particles, nano clay, porous carbon, calcium chloride (CaCl₂), sodium chloride (NaCl), or bentonite clay.

In an embodiment, the moisture-absorbing agent includes at least one organic moisture-absorbing agent selected from a hemicellulose resin, pectin, silica gel, or starch particles.

In an embodiment, the moisture-absorbing agent is included in particle form, and a particle size of the moisture-absorbing agent is from about 10 nm to about 100 nm.

In an embodiment, a content of the moisture-absorbing agent is from about 1 wt % to about 30 wt % relative to a total composition of the overcoat layer.

In an embodiment, a thickness of the overcoat layer is from about 3 μm to about 30 μm.

According to an aspect, a display device includes a substrate, a light-emitting element layer disposed on the substrate and including a plurality of emission areas, an encapsulation layer disposed on the light-emitting element layer, a touch sensing layer disposed on the encapsulation layer, a scattering layer disposed on the touch sensing layer, a color filter layer disposed on the scattering layer and the touch sensing layer, and an overcoat layer disposed on the color filter layer, wherein the overcoat layer has a modulus in the range of about 3 GPa to about 60 GPa, and includes a base resin and a moisture-absorbing agent dispersed in the base resin.

In an embodiment, the emission areas includes a first emission area, a second emission area, and a third emission area, and the scattering layer overlaps with the first and third emission areas and does not overlap with the second emission area.

In an embodiment, the first emission area emits red light, the second emission area emits blue light, and the third emission area emits green light.

In an embodiment, the display device further includes an optical layer in film form bonded onto the overcoat layer.

In an embodiment, the base resin includes at least one of Chemical Formulas A, B, D, and E:

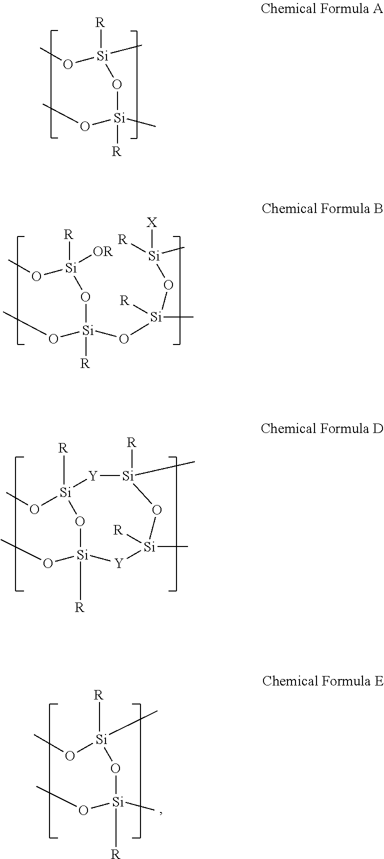

where in Chemical Formula B or D, X and Y are each independently R or [(SiO_{3/2}R)₄₊₂ₙO] (where n is 1 to 10), and where R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms, where the phenyl group is either substituted with a substituent or unsubstituted and the substituent is selected from hydrogen, deuterium, halogen, an amino group, an epoxy group, a cyclohexyl epoxy group, an acryl group, a methacryl group, a thiol group, an isocyanate group, a nitrile group, or a nitro group.

In an embodiment, the base resin includes at least one compound selected from Chemical Formulas 1 through 14, where Chemical Formulas 1 through 9 are as follows:

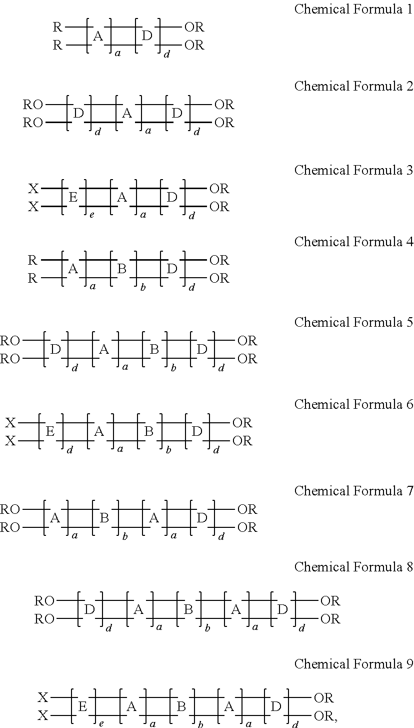

where in Chemical Formulas 1 through 9, R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms, where the phenyl group is either substituted with a substituent or unsubstituted; the substituent is independently selected from hydrogen, deuterium, halogen, an amino group, an epoxy group, a cyclohexyl epoxy group, an acryl group, a methacryl group, a thiol group, an isocyanate group, a nitrile group, and a nitro group, X is independently selected from R or [(SiO_{3/2}R)₄₊₂ₙO] (where n is 1 to 10) and a, b, d, and e are integers from 1 to 1000, Chemical Formulas 10 through 14 are as follows:

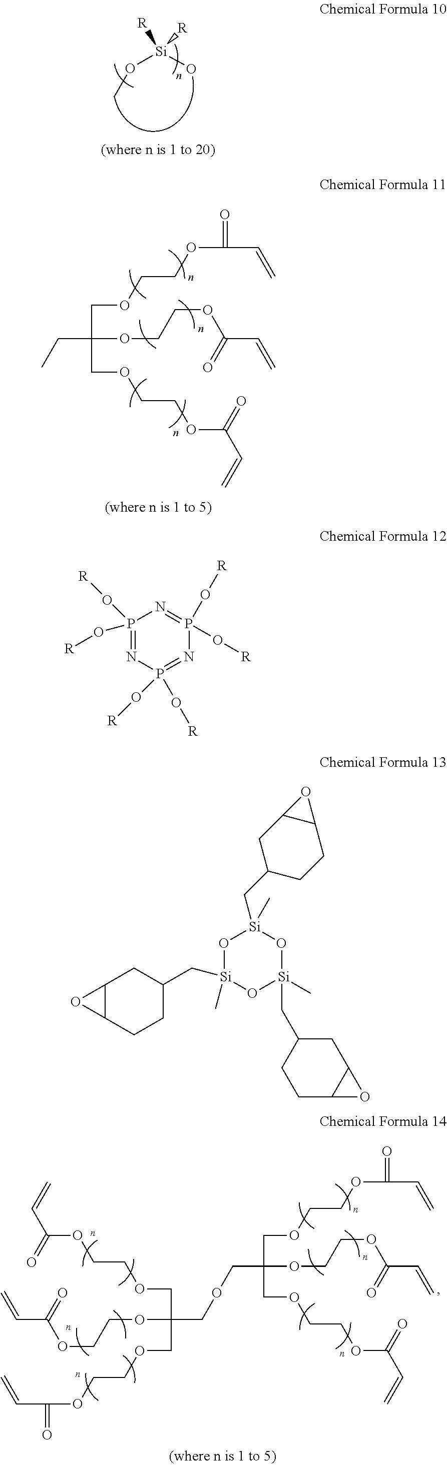

and in Chemical Formulas 10 and 12, R is selected from

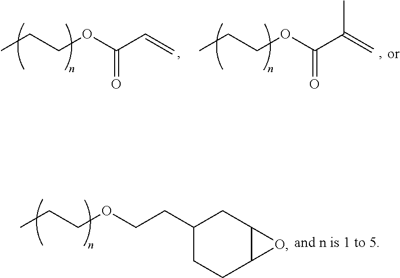

In an embodiment, the moisture-absorbing agent includes at least one inorganic moisture-absorbing agent from zeolite, porous silica, metal-organic frameworks (MOFs), alumina particles, nano clay, porous carbon, calcium chloride (CaCl₂), sodium chloride (NaCl), or bentonite clay.

In an embodiment, the moisture-absorbing agent includes at least one organic moisture-absorbing agent selected from a hemicellulose resin, pectin, silica gel, or starch particles.

In an embodiment, the moisture-absorbing agent is included in particle form, and a particle size of the moisture-absorbing agent is from about 10 nm to about 100 nm.

In an embodiment, a content of the moisture-absorbing agent is from about 1 wt % to about 30 wt % relative to a total composition of the overcoat layer.

In an embodiment, a thickness of the overcoat layer is from about 3 μm to about 30 μm.

In an embodiment, by forming an overcoat layer with high hardness and moisture absorption characteristics, which substitutes for a cover substrate, degradation in the reliability of a display device can be prevented. Specifically, by forming an overcoat layer with a hardness of about 3 GPa or more, the display device can be protected from external impact, and by forming an overcoat layer that contains a moisture-absorbing agent, defects in a color filter layer caused by moisture infiltration from the outside can be prevented.

It should be noted that the effects of the invention are not limited to those described above, and other effects of the invention will be apparent from the following description.

### BRIEF DESCRIPTION OF THE DRAWINGS

The above and other aspects and features of the invention will become more apparent by describing in detail embodiments thereof with reference to the attached drawings, in which:

FIG. 1 is a plan view of an electronic device, according to an embodiment;

FIG. 2 is a perspective view illustrating the folded state of a foldable display device, according to an embodiment;

FIG. 3 is a perspective view illustrating the unfolded state of the foldable display device of FIG. 2, according to an embodiment;

FIG. 4 is a perspective view illustrating a display device included in the electronic device of FIG. 1, according to an embodiment;

FIG. 5 is a cross-sectional view of the display device of FIG. 4, as viewed from a side, according to an embodiment;

FIG. 6 is a plan view illustrating the display layer of the display device, according to an embodiment;

FIG. 7 is a plan view illustrating the touch sensing layer of the display device, according to an embodiment;

FIG. 8 is a plan view illustrating emission regions of the display device, according to an embodiment;

FIG. 9 is a cross-sectional view taken along line X-X′ of FIG. 8, according to an embodiment;

FIG. 10 is an enlarged cross-sectional view of the overcoat layer of the display device, according to an embodiment;

FIG. 11 is an image of a display panel, according to a comparative example; and

FIG. 12 is an image of a display panel, according to an embodiment.

### DETAILED DESCRIPTION

The invention will now be described more fully hereinafter with reference to the accompanying drawings, in which preferred embodiments are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Each of the features of the various embodiments may be combined with each other, in part or in whole, and technically various interlocking and driving are possible. Each embodiment may be implemented independently of each other or may be implemented together in an association.

Embodiments will be described with reference to the attached drawings.

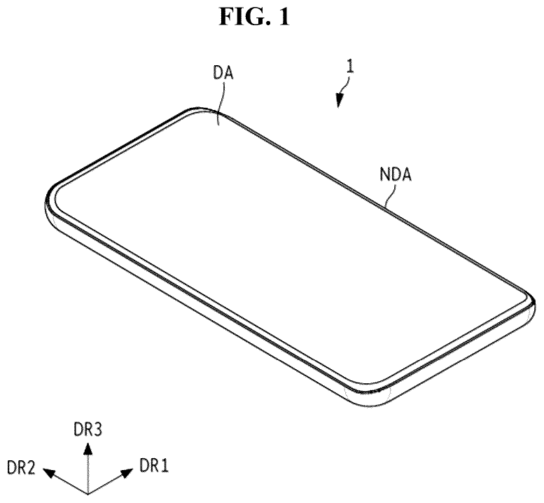

FIG. 1 is a plan view of an electronic device, according to an embodiment.

In an embodiment and referring to FIG. 1, an electronic device 1 displays videos or still images. The electronic device 1 may refer to any electronic device that provides a display screen. For example, televisions (TVs), laptops, monitors, billboards, Internet of Things (IoT) devices, mobile phones, smartphones, tablet personal computers (PCs), electronic watches, smartwatches, watch phones, head-mounted displays (HMDs), mobile communication terminals, electronic notepads, e-books, portable multimedia players (PMP), navigation devices, game consoles, digital cameras, camcorders, and the like may be included in examples of the electronic device 1.

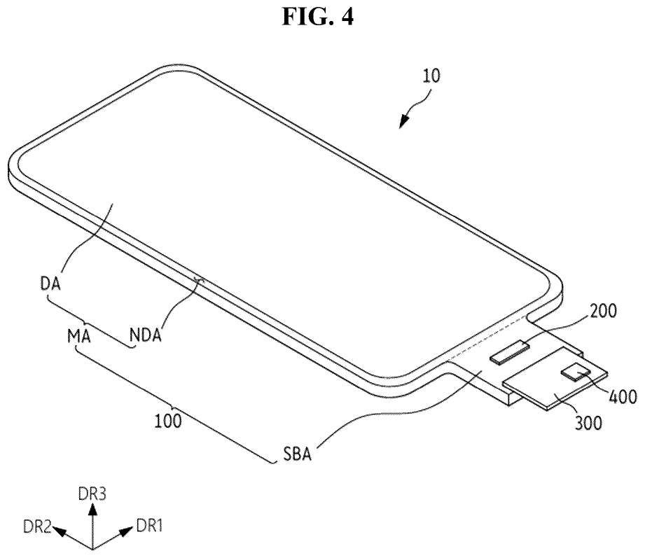

In an embodiment, the electronic device 1 may include a display device 10 in FIG. 4 that provides the display screen. Examples of the display device 10 include inorganic light-emitting diode display devices, organic light-emitting display devices, quantum dot light-emitting display devices, plasma display devices, field-emission display (FED) devices, and others. An organic light-emitting diode display device will hereinafter be described as being applied as one type of display device, but the invention is not limited thereto, and other display devices may also be applicable within the technical scope of the invention.

In an embodiment, the shape of the electronic device 1 may vary in different forms. For example, the electronic device 1 may have a shape such as a horizontally elongated rectangle, a vertically elongated rectangle, a square, a rectangle with rounded corners, another polygon, or a circle. The shape of a display area DA of the electronic device 1 may also be similar to the overall shape of the electronic device 1. In FIG. 1, an electronic device 1 with a rectangular shape that extends longer in a second direction DR2 is illustrated.

In an embodiment, the electronic device 1 may include the display area DA and a non-display area NDA. The display area DA is where the screen may be displayed, and the non-display area NDA is where the screen is not displayed. The display area DA may also be referred to as an active area, and the non-display area NDA may also be referred to as an inactive area. The display area DA may generally occupy the center of the electronic device 1.

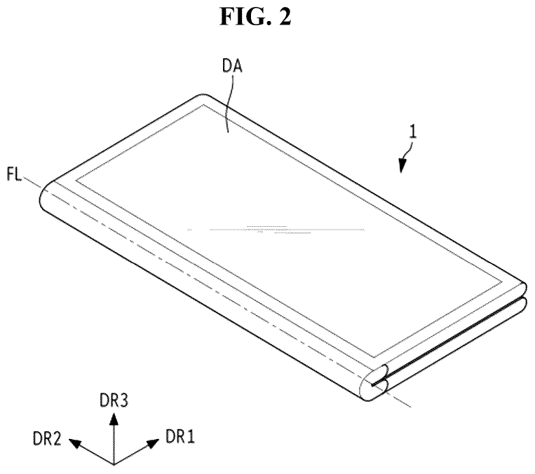

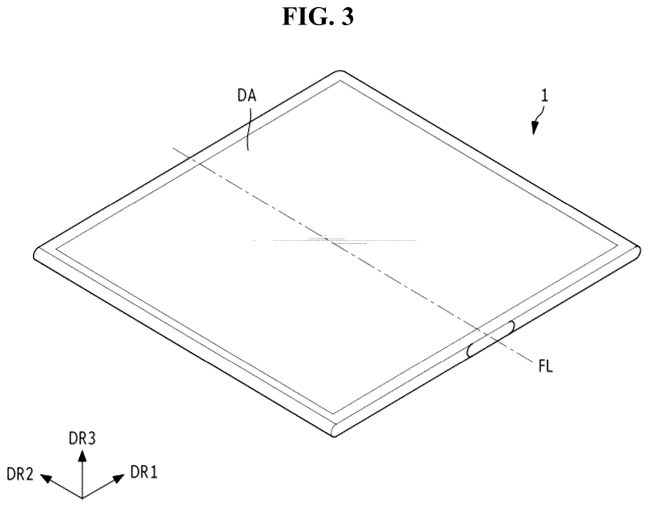

FIG. 2 is a perspective view illustrating the folded state of a foldable display device, according to an embodiment. FIG. 3 is a perspective view illustrating the unfolded state of the foldable display device of FIG. 2, according to an embodiment.

In an embodiment and referring to FIGS. 2 and 3, the electronic device 1 may be a foldable display device, where the electronic device 1 may be foldable along a folding axis FL. The display area DA may be arranged on the outer side and/or inner side of the electronic device 1. In an embodiment, as illustrated in FIGS. 2 and 3, the display area DA may be arranged on both the outer and inner sides of the electronic device 1.

In an embodiment, the display area DA may be arranged on the outer side of the electronic device 1, where the outer surface of the folded electronic device 1 may include the display area DA, and the inner surface of the unfolded electronic device 1 may include the display area DA.

FIG. 4 is a perspective view illustrating a display device included in the electronic device, according to an embodiment.

In an embodiment and referring to FIG. 4, the electronic device 1 may include a display device 10, where the display device 10 may provide the screen displayed by the electronic device 1. The display device 10 may have a planar shape similar to the electronic device 1. For example, the display device 10 may have a shape similar to a rectangle with short sides in a first direction DR1 and long sides in a second direction DR2. The corners where the short sides in the first direction DR1 and the long sides in the second direction DR2 meet may be rounded to have a curvature, but may also be formed at right angles without limitation. The planar shape of the display device 10 is not limited to a rectangle and may be formed in other polygons, circles, or ovals.

In an embodiment, the display device 10 may include a display panel 100, a display driving unit 200, a circuit board 300, and a touch driving unit 400.

In an embodiment, the display panel 100 may include a main area MA and a sub-area SBA.

In an embodiment, the main area MA may include a display area DA that contains pixels displaying images and a non-display area NDA that is arranged around the display area DA. The display area DA may emit light from a plurality of emission or aperture regions. For example, the display panel 100 may include pixel circuitry containing switching elements, a pixel defining film that defines the emission regions or aperture regions, and self-light-emitting elements.

For example, in an embodiment, the self-light-emitting elements may include at least one of organic light-emitting diodes (OLEDs) including an organic light-emitting layer, quantum dot light-emitting diodes (quantum dot LEDs) including a quantum dot light-emitting layer, inorganic light-emitting diodes (inorganic LEDs) including an inorganic semiconductor, or micro light-emitting diodes (Micro LEDs), but the invention is not limited thereto.

In an embodiment, the non-display area NDA may be the area outside the display area DA and may be defined as the edge area of the main area MA of the display panel 100. The non-display area NDA may include a gate driving unit (not illustrated) that supplies gate signals to gate lines and fan-out lines (not illustrated) that connect the display driving unit 200 to the display area DA.

In an embodiment, the sub-area SBA may be an area extending from one side of the main area MA and may include a flexible material that allows for bending, folding, or rolling. For example, when the sub-area SBA is bent, it may overlap with the main area MA in a thickness direction (i.e., a third direction DR3). The sub-area SBA may include a pad unit connected to the display driving unit 200 and the circuit board 300. In another embodiment, the sub-area SBA may be omitted, and the display driving unit 200 and the pad unit may be arranged in the non-display area NDA.

In an embodiment, the display driving unit 200 may output signals and voltages to drive the display panel 100. The display driving unit 200 may supply data voltages to data lines. The display driving unit 200 may supply power voltages to power lines and supply gate control signals to the gate driving unit. The display driving unit 200 may be formed as an integrated circuit (IC) and mounted on the display panel 100 using a chip-on-glass (COG) method, a chip-on-plastic (COP) method, or an ultrasonic bonding method. For example, the display driving unit 200 may be arranged in the sub-area SBA and may overlap with the main area MA in the thickness direction when the sub-area SBA is bent. In another example, the display driving unit 200 may be mounted on the circuit board 300.

In an embodiment, the circuit board 300 may be attached to the pad unit of the display panel 100 using an anisotropic conductive film (ACF). Lead lines of the circuit board 300 may be electrically connected to the pad unit of the display panel 100. The circuit board 300 may be a flexible film such as a flexible printed circuit board (FPCB), a printed circuit board (PCB), or a chip-on-film (COF).

In an embodiment, the touch driving unit 400 may be mounted on the circuit board 300 and may be connected to a touch sensing unit of the display panel 100. The touch driving unit 400 may supply touch driving signals to a plurality of touch electrodes and sense changes in capacitance between the plurality of touch electrodes. For example, the touch driving signals may be pulse signals with a predetermined frequency. The touch driving unit 400 may calculate input presence and input coordinates based on the amount of capacitance changes between the plurality of touch electrodes. The touch driving unit 400 may be formed as an IC.

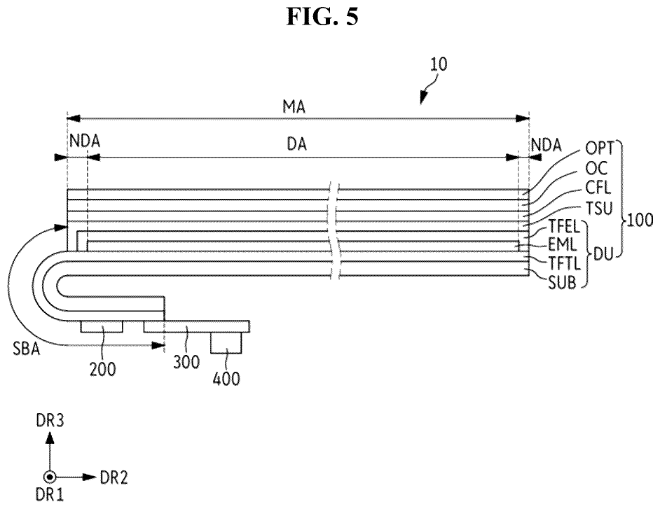

FIG. 5 is a cross-sectional view of the display device of FIG. 4, as viewed from a side, according to an embodiment.

In an embodiment and referring to FIG. 5, the display panel 100 may include a display layer DU, a touch sensing layer TSU, a color filter layer CFL, an overcoat layer OC, and an optical layer OPT. The display layer DU may include a substrate SUB, a thin-film transistor (TFT) layer TFTL, a light-emitting element layer EML, and an encapsulation layer TFEL.

In an embodiment, the substrate SUB may be a base substrate or a base member, where the substrate SUB may be a flexible substrate capable of bending, folding, or rolling. For example, the substrate SUB may include a polymer resin such as polyimide (PI), but the invention is not limited thereto. In another example, the substrate SUB may include glass or metal.

In an embodiment, the TFT layer TFTL may be disposed on the substrate SUB. The TFT layer TFTL may include a plurality of TFTs that form pixel circuits for pixels. The TFT layer TFTL may further include gate lines, data lines, power lines, gate control lines, fan-out lines connecting the display driving unit 200 and the data lines, and lead lines connecting the display driving unit 200 to the pad unit. Each of the TFTs may include a semiconductor region, a source electrode, a drain electrode, and a gate electrode. For example, when the gate driving unit is formed on one side of the non-display area NDA of the display panel 100, the gate driving unit may include the TFTs.

In an embodiment, the TFT layer TFTL may be disposed in the display area DA, the non-display area NDA, and the sub-area SBA. The TFTs, gate lines, data lines, and power lines for the respective pixels in the TFT layer TFTL may be disposed in the display area DA. The gate control lines and fan-out lines of the TFT layer TFTL may be disposed in the non-display area NDA. The lead lines of the TFT layer TFTL may be disposed in the sub-area SBA.

In an embodiment, the light-emitting element layer EML may be disposed on the TFT layer TFTL and may include a plurality of light-emitting elements that include pixel electrodes, a common electrode, and a light-emitting layer and thereby emit light, and a pixel defining film that define the pixels. The plurality of light-emitting elements of the light-emitting element layer EML may be disposed in the display area DA.

In an embodiment, the light-emitting layer may be an organic light-emitting layer that includes an organic material, where the light-emitting layer may also include a hole transport layer, an organic light-emitting layer, and an electron transport layer. When the pixel electrodes receive voltage through the TFTs of the TFT layer TFTL and the common electrode receives a cathode voltage, holes and electrons may move into the organic light-emitting layer via the hole transport layer and the electron transport layer, respectively, and combine in the organic light-emitting layer to emit light.

In other embodiments, the light-emitting element may include a quantum dot light-emitting diode that includes a quantum dot light-emitting layer, an inorganic light-emitting diode that includes an inorganic semiconductor, or a micro light-emitting diode.

In an embodiment, the encapsulation layer TFEL may cover the upper surface and sides of the light-emitting element layer EML and may protect the light-emitting element layer EML. The encapsulation layer TFEL may include at least one inorganic film and at least one organic film for encapsulating the light-emitting element layer EML.

In an embodiment, the touch sensing layer TSU may be disposed on the encapsulation layer TFEL and may include a plurality of touch electrodes for detecting a user's touch using a capacitive method, and touch lines connecting the plurality of touch electrodes to the touch driving unit 400. For example, the touch sensing layer TSU may detect the user's touch using a mutual capacitance method or a self-capacitance method.

In an embodiment, the plurality of touch electrodes of the touch sensing layer TSU may be disposed in a touch sensor area that overlaps the display area DA. The touch lines of the touch sensing layer TSU may be disposed in a touch peripheral area that overlaps with the non-display area NDA.

In an embodiment, the color filter layer CFL may be disposed on the touch sensing layer TSU and may include a plurality of color filters corresponding to the plurality of emission regions, respectively. Each of the color filters may selectively transmit light of a particular wavelength and block or absorb light of other wavelengths. The color filter layer CFL may absorb some of the light coming from outside the display device 10, thereby reducing reflected light caused by external light. Accordingly, the color filter layer CFL may prevent color distortion caused by reflection of external light.

In an embodiment, by being directly disposed on the touch sensing layer TSU, the color filter layer CFL may eliminate the need for a separate substrate for the color filter layer CFL in the display device 10. As a result, the thickness of the display device 10 may be relatively small.

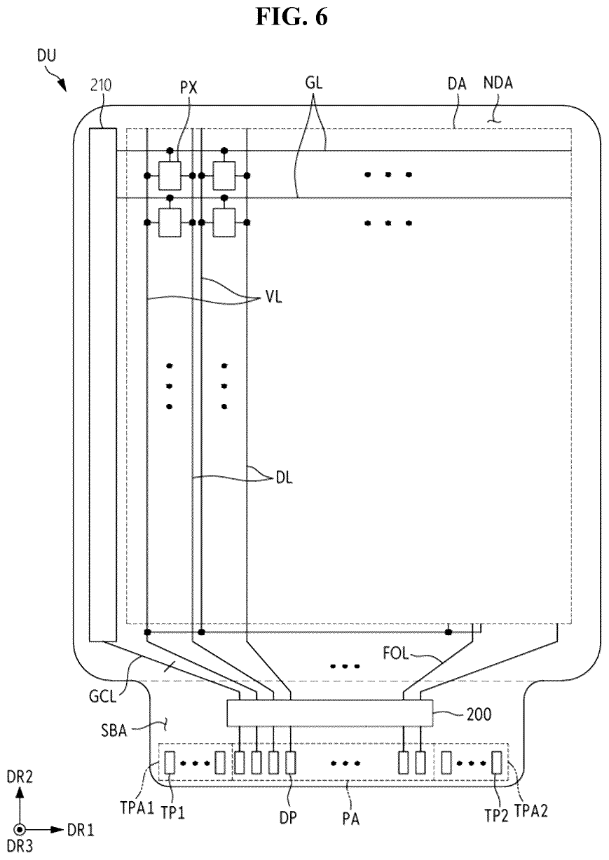

FIG. 6 is a plan view illustrating the display layer of the display device, according to an embodiment.

In an embodiment and referring to FIG. 6, the display layer DU may include a display area DA and a non-display area NDA.

In an embodiment, the display area DA may be disposed in the center of the display panel 100. A plurality of pixels PX, a plurality of gate lines GL, a plurality of data lines DL, and a plurality of power lines VL may be disposed in the display area DA. Each of the pixels PX may be defined as a minimal unit emitting light.

In an embodiment, the gate lines GL may supply gate signals received from the gate driving unit 210 to the pixels PX, where the gate lines GL may extend in the first direction DR1 and may be spaced apart from each other in the second direction DR2, which intersects the first direction DR1.

In an embodiment, the data lines DL may supply data voltages received from the display driving unit 200 to the pixels PX, where the data lines DL may extend in the second direction DR2 and may be spaced apart from each other in the first direction DR1.

In an embodiment, the power lines VL may supply power voltages received from the display driving unit 200 to the pixels PX, where the power voltages may include at least one of a driving voltage, an initialization voltage, a reference voltage, or a low-potential voltage. The power lines VL may extend in the second direction DR2 and may be spaced apart from each other in the first direction DR1.

In an embodiment, the non-display area NDA may surround the display area DA. The non-display area NDA may include a gate driving unit 210, fan-out lines FOL, and gate control lines GCL. The gate driving unit 210 may generate a plurality of gate signals based on the gate control signals and sequentially supply the plurality of gate signals to the plurality of gate lines GL in a predetermined order.

In an embodiment, the fan-out lines FOL may extend from the display driving unit 200 to the display area DA and may supply data voltages received from the display driving unit 200 to the data lines DL.

In an embodiment, the gate control lines GCL may extend from the display driving unit 200 to the gate driving unit 210 and may supply gate control signals received from the display driving unit 200 to the gate driving unit 210.

In an embodiment, the sub-area SBA may include the display driving unit 200, a pad area PA, and first and second touch pad areas TPA1 and TPA2.

In an embodiment, the display driving unit 200 may output signals and voltages for driving the display panel 100 to the fan-out lines FOL, where the display driving unit 200 may supply data voltages to the data lines DL via the fan-out lines FOL. The data voltages may be supplied to the pixels PX and may control the brightness of the pixels PX. The display driving unit 200 may supply gate control signals to the gate driving unit 210 via the gate control lines GCL.

In an embodiment, the pad area PA, the first touch pad area TPA1, and the second touch pad area TPA2 may be disposed at the edge of the sub-area SBA. The pad area PA, the first touch pad area TPA1, and the second touch pad area TPA2 may be electrically connected to the circuit board 300 using a material such as an ACF or self-assembly anisotropic conductive paste (SAP). The first touch pad area TPA1 may include first touch pads TP1, and the second touch pad area TPA2 may include second touch pads TP2. The first and second pad areas TPA1 and TPA2 may both be electrically connected to the circuit board 300.

In an embodiment, the pad area PA may include a plurality of display pad units DP, where the display pad units DP may be connected to a graphic system via the circuit board 300. The display pad units DP may receive digital video data from the circuit board 300 and supply the digital video data to the display driving unit 200.

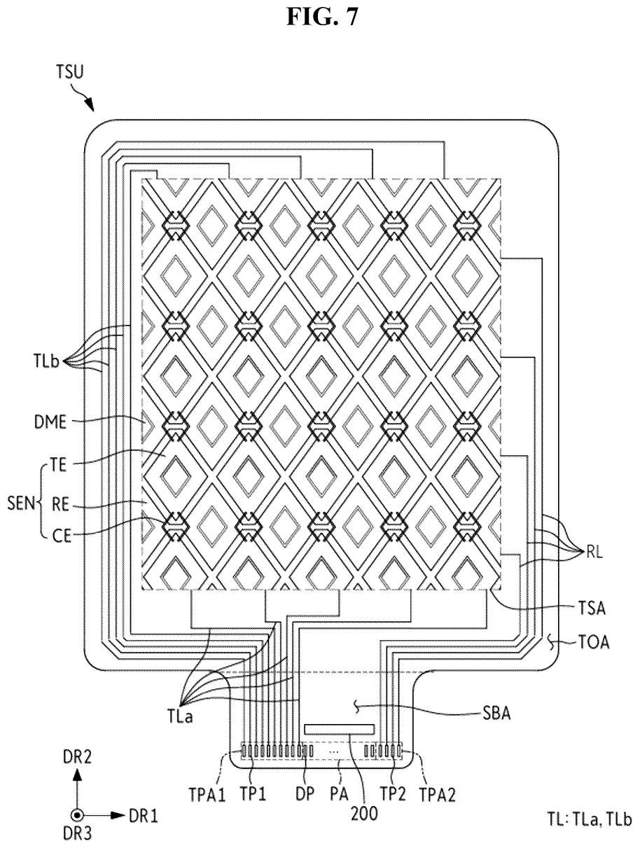

FIG. 7 is a plan view illustrating the touch sensing layer of the display device, according to an embodiment.

In an embodiment and referring to FIG. 7, the touch sensing layer TSU may include a touch sensor area TSA that detects the user's touch, and a touch peripheral area TOA that is disposed around the touch sensor area TSA. The touch sensor area TSA may be disposed in the display area DA of the display device 10, and the touch peripheral area TOA may be disposed in the non-display area NDA of the display device 10.

In an embodiment, the touch sensor area TSA may include a plurality of touch electrodes SEN and a plurality of dummy electrodes DME, where the touch electrodes SEN may form mutual capacitance or self-capacitance to detect a touch by an object or a person. The touch electrodes SEN may include a plurality of driving electrodes TE, a plurality of sensing electrodes RE, and bridge electrodes CE.

In an embodiment, the driving electrodes TE may be arranged in the first and second directions DR1 and DR2, respectively. The driving electrodes TE may be spaced apart from each other in the directions DR1 and DR2. Adjacent driving electrodes TE in the second direction DR2 may be electrically connected through the bridge electrodes CE.

In an embodiment, the driving electrodes TE may be connected to the first touch pads TP1 through driving lines TL. The driving lines TL may include lower driving lines TLa and upper driving lines TLb. For example, the driving electrodes TE disposed at the lower side of the touch sensor area TSA may be connected to the first touch pads TP1 through the lower driving lines TLa, and the driving electrodes TE disposed at the upper side of the touch sensor area TSA may be connected to the first touch pads TP1 through the upper driving lines TLb. The lower driving lines TLa may extend to the first touch pads TP1 along the lower side of the touch peripheral area TOA. The upper driving lines TLb may extend to the first touch pads TP1 along the upper, left, and lower sides of the touch peripheral area TOA. The first touch pads TP1 may be connected to the touch driving unit 400 via the circuit board 300.

In an embodiment, the bridge electrodes CE may be bent at least once. For example, the bridge electrodes CE may have an angle bracket shape (“<” or “>”), but the planar shape of the bridge electrodes CE is not limited thereto. Adjacent driving electrodes TE in the second direction DR2 may be connected by multiple bridge electrodes CE, and even if any of the bridge electrodes CE are disconnected, the driving electrodes TE may remain reliably connected through the other non-disconnected bridge electrodes CE. The adjacent driving electrodes TE in the second direction DR2 may be connected by two bridge electrodes CE, but the number of bridge electrodes CE is not limited to this.

In an embodiment, the bridge electrodes CE may be disposed on a different layer from the driving electrodes TE and the sensing electrodes RE. Adjacent sensing electrodes RE in the first direction DR1 may be electrically connected through connectors disposed on the same layer as the driving electrodes TE or the sensing electrodes RE, and the adjacent driving electrodes TE adjacent in the second direction DR2 may be electrically connected through the bridge electrodes CE, which are disposed on a different layer than the driving electrodes TE or the sensing electrodes RE. Therefore, even if the bridge electrodes CE overlap with the sensing electrodes RE in a Z-axis direction, the driving electrodes TE and the sensing electrodes RE may remain insulated from each other. Additionally, mutual capacitance may be formed between the driving electrodes TE and the sensing electrodes RE.

In an embodiment, the sensing electrodes RE may extend in the first direction DR1 and may be spaced apart from each other in the second direction DR2. The sensing electrodes RE may be arranged in the directions DR1 and DR2, and adjacent sensing electrodes RE in the first direction DR1 may be electrically connected through connectors.

In an embodiment, the sensing electrodes RE may be connected to the second touch pads TP2 through sensing lines RL. For example, the sensing electrodes RE disposed on the right side of the touch sensor area TSA may be connected to the second touch pads TP2 through the sensing lines RL. The sensing lines RL may extend to the second touch pads TP2 via the right and lower sides of the touch peripheral area TOA. The second touch pads TP2 may be connected to the touch driving unit 400 via the circuit board 300.

In an embodiment, each of the dummy electrodes DME may be surrounded by the driving electrodes TE or the sensing electrodes RE, where each of the dummy electrodes DME may be spaced apart and insulated from the driving electrodes TE or the sensing electrodes RE. Therefore, the dummy electrodes DME may be electrically floated.

In an embodiment, the pad area PA, the first touch pad area TPA1, and the second touch pad area TPA2 may be disposed at the edge of the sub-area SBA. The pad area PA, the first touch pad area TPA1, and the second touch pad area TPA2 may be electrically connected to the circuit board 300 using a low-resistance, high-reliability material such as an ACF or SAP.

In an embodiment, the first touch pad area TPA1 may be disposed on one side of the pad area PA and may include a plurality of first touch pads TP1. The first touch pads TP1 may be electrically connected to the touch driving unit 400 disposed on the circuit board 300. The first touch pads TP1 may supply touch driving signals to the driving electrodes TE via the driving lines TL.

In an embodiment, the second touch pad area TPA2 may be disposed on the other side of the pad area PA and may include a plurality of second touch pads TP2. The second touch pads TP2 may be electrically connected to the touch driving unit 400 disposed on the circuit board 300. The touch driving unit 400 may receive touch sensing signals through the sensing lines RL connected to the second touch pad units TP2 and may detect changes in mutual capacitance between the driving electrodes TE and the sensing electrodes RE.

In another embodiment, the touch driving unit 400 may supply touch driving signals to both the driving electrodes TE and the sensing electrodes RE and may receive touch sensing signals from both the driving electrodes TE and the sensing electrodes RE. The touch driving unit 400 may sense charge changes in both the driving electrodes TE and the sensing electrodes RE based on the touch sensing signals.

FIG. 7 illustrates an embodiment where a structure in which the touch electrodes SEN in the touch sensing layer TSU are connected in a diamond shape in the directions DR1 and DR2, but the invention is not limited thereto. In another embodiment, the touch electrodes SEN may be formed in a mesh shape.

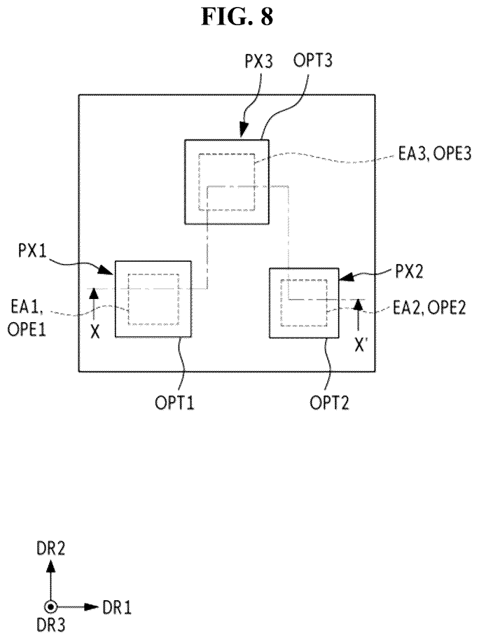

FIG. 8 is a plan view illustrating emission regions of the display device, according to an embodiment.

In an embodiment and referring to FIG. 8, the display device 10 may include a plurality of first, second, and third pixels PX1, PX2, and PX3, respectively, that are arranged in the display area DA. The pixels PX1, PX2, and PX3 may be repeatedly arranged along the directions DR1 and DR2. For example, based on the first pixel PX1, the second pixel PX2 may be arranged in the first direction DR1, and the third pixel PX3 may be arranged in the second direction DR2.

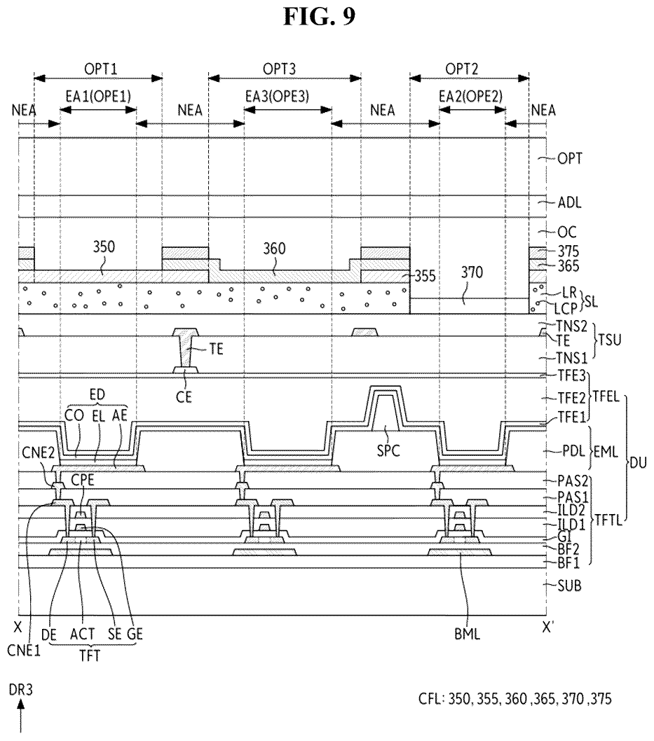

In an embodiment, the pixels PX1, PX2, and PX3 may include first, second, and third emission areas EA1, EA2, and EA3, respectively, that emit light of different colors, where the emission areas EA1, EA2, and EA3 may emit red light, blue light, and green light, respectively, and the color of the light emitted from each of the emission regions EA1, EA2, and EA3 may vary depending on the type of the light-emitting elements (“ED” in FIG. 9) disposed in the light-emitting element layer EML, as will be described later. In an embodiment, the emission areas EA1, EA2, and EA3 may emit red light, blue light, and green light, respectively, but the invention is not limited thereto.

In an embodiment, the emission areas EA1, EA2, and EA3 may be defined by a plurality of first, second, and third apertures OPE1, OPE2, and OPE3, respectively, that are formed in the pixel defining layer PDL of the light-emitting element layer EML, as will be described later. For example, the first emission region EA1 may be defined by the first aperture OPE1 of the pixel defining layer PDL, the second emission region EA2 may be defined by the second aperture OPE2 of the pixel defining layer PDL, and the third emission region EA3 may be defined by the third aperture OPE3 of the pixel defining layer PDL.

In an embodiment, the emission areas EA1, EA2, and EA3 may have different areas or sizes. In the embodiment of FIG. 8, the area of the first emission region EA1 may be larger than the area of the second emission region EA2 and smaller than the area of the third emission region EA3. The area of the second emission region EA2 may be smaller than the area of the third emission region EA3. The area of the emission areas EA1, EA2, and EA3 may vary depending on the size of the apertures OPE1, OPE2, and OPE3 formed in the pixel defining layer PDL. The intensity of the light emitted from the emission areas EA1, EA2, and EA3 may vary depending on the area of the emission areas EA1, EA2, and EA3, and by adjusting the area of the emission areas EA1, EA2, and EA3, the color of the screen displayed by the display device 10 or the electronic device 1 may be controlled.

In the embodiment of FIG. 8, the emission areas EA1, EA2, and EA3 are illustrated as being different from each other, but the invention is not limited thereto. In another embodiment, the emission areas EA1, EA2, and EA3 may have the same area, or the relationship between the areas of the emission areas EA1, EA2, and EA3 may differ from that illustrated in FIG. 8. The area of the emission areas EA1, EA2, and EA3 may be freely adjusted depending on the desired color of the screen for the display device 10 or the electronic device 1. Additionally, the area of the emission areas EA1, EA2, and EA3 is related to light efficiency, the lifespan of the light-emitting elements ED, etc., and may have a trade-off relationship with reflection of external light. The area of the emission areas EA1, EA2, and EA3 may be adjusted in consideration of these factors.

In an embodiment, the apertures OPE1, OPE2, and OPE3 and a plurality of light output portions OPT1, OPT2, and OPT3 are illustrated as being rectangular, but the invention is not limited thereto. Various other shapes, such as oval or polygonal shapes with curved edges, may also be applicable to the apertures OPE1, OPE2, and OPE3 and the light output portions OPT1, OPT2, and OPT3.

In an embodiment, the pixels PX1, PX2, and PX3 may include the emission regions EA1, EA2, and EA3, respectively, that are arranged adjacent to each other to represent white gradation, but the invention is not limited thereto. The combination of the emission regions EA1, EA2, and EA3 that constitute a pixel group may vary depending on the arrangement of the emission regions EA1, EA2, and EA3 and the colors of light emitted by the emission regions EA1, EA2, and EA3.

In an embodiment and referring again to FIG. 5, the color filter layer CFL may be disposed on the touch sensing layer TSU. The color filter layer CFL may be arranged to correspond to each of the emission regions EA1, EA2, and EA3. The color filter layer CFL may transmit light of the colors corresponding to the emission regions EA1, EA2, and EA3, and absorb or block light of other wavelengths. Additionally, the color filter layer CFL may absorb or block light between the emission regions EA1, EA2, and EA3 to prevent color mixing.

In an embodiment, the overcoat layer OC may be disposed on the color filter layer CFL. The overcoat layer OC may flatten the steps in the color filter layer CFL and protect the color filter layer CFL. The overcoat layer OC may include a moisture-absorbing agent and may thereby prevent defects in the color filter layer CFL caused by moisture penetration. This will be described later.

In an embodiment, an optical layer OPT may be disposed on the overcoat layer OC. The optical layer OPT is for improving the optical characteristics of the display device and may include, for example, an anti-glare member or an anti-reflection member, but is not limited thereto. The optical layer OPT may also include a fingerprint-resistant member, among others.

The display device, according to an embodiment, will hereinafter be described in further detail with reference to other figures.

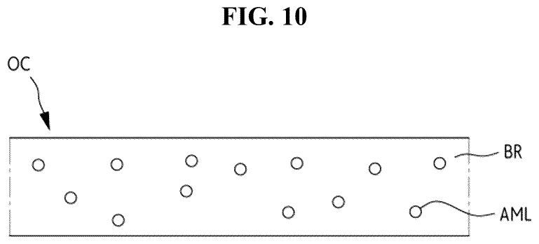

FIG. 9 is a cross-sectional view taken along line X-X′ of FIG. 8, according to an embodiment. FIG. 10 is an enlarged cross-sectional view of the overcoat layer of the display device, according to one embodiment.

In an embodiment and referring to FIG. 9 and further to FIG. 8, the display panel 100 of the display device 10 may include the display layer DU, the touch sensing layer TSU, a scattering layer SL, the color filter layer CFL, the overcoat layer OC, and the optical layer OPT. The display layer DU may include a substrate SUB, a TFT layer TFTL, a light-emitting element layer EML, and an encapsulation layer TFEL.

In an embodiment, the substrate SUB may be a base substrate or a base member, where the substrate SUB may be a flexible substrate capable of bending, folding, or rolling. For example, the substrate SUB may include a polymer resin such as PI, but the invention is not limited thereto. In another example, the substrate SUB may include a glass material or a metal material.

In an embodiment, the TFT layer TFTL may include a first buffer layer BF1, a lower metal layer BML, a second buffer layer BF2, TFTs TFT, a gate insulation layer GI, a first interlayer insulation layer ILD1, a capacitor electrode CPE, a second interlayer insulation layer ILD2, first connection electrodes CNE1, a first passivation layer PAS1, second connection electrodes CNE2, and a second passivation layer PAS2.

In an embodiment, the first buffer layer BF1 may be disposed on the substrate SUB. The first buffer layer BF1 may include an inorganic film that can prevent the penetration of air or moisture. For example, the first buffer layer BF1 may include a plurality of alternating stacked inorganic films.

In an embodiment, the lower metal layer BML may be disposed on the first buffer layer BF1. For example, the lower metal layer BML may be formed as a single layer or a multilayer composed of one of molybdenum (Mo), aluminum (Al), chromium (Cr), gold (Au), titanium (Ti), nickel (Ni), neodymium (Nd), tantalum (Ta), and copper (Cu) or an alloy thereof.

In an embodiment, the second buffer layer BF2 may cover the first buffer layer BF1 and the lower metal layer BML. The second buffer layer BF2 may include an inorganic film that can prevent the penetration of air or moisture. For example, the second buffer layer BF2 may include a plurality of alternating stacked inorganic films.

In an embodiment, the TFTs TFT may be disposed on the second buffer layer BF2 and may form the pixel circuits of a plurality of pixels. For example, the TFTs TFT may be driving transistors or switching transistors of the pixel circuits. Each of the TFTs TFT may include a semiconductor layer ACT, a source electrode SE, a drain electrode DE, and a gate electrode GE.

In an embodiment, the semiconductor layer ACT may be disposed on the second buffer layer BF2 and may overlap with the lower metal layer BML and the gate electrode GE in the thickness direction and may be insulated from the gate electrode GE by the gate insulation layer GI. Portions of the semiconductor layer ACT may be doped to form the source electrode SE and the drain electrode DE.

In an embodiment, the gate electrode GE may be disposed on the gate insulation layer GI and may overlap with the semiconductor layer ACT with the gate insulation layer GI interposed therebetween.

In an embodiment, the gate insulation layer GI may be disposed on the semiconductor layer ACT. For example, the gate insulation layer GI may cover the semiconductor layer ACT and the second buffer layer BF2 and may insulate the semiconductor layer ACT from the gate electrode GE. The gate insulation layer GI may include contact holes through which the first connection electrodes CNE1 pass.

In an embodiment, the first interlayer insulation layer ILD1 may cover the gate electrode GE and the gate insulation layer GI. The first interlayer insulation layer ILD1 may include contact holes through which the first connection electrodes CNE1 pass. The contact holes of the first interlayer insulation layer ILD1 may be connected to the contact holes of the gate insulation layer GI and the contact holes of the second interlayer insulation layer ILD2.

In an embodiment, the capacitor electrode CPE may be disposed on the first interlayer insulation layer ILD1 and may overlap with the gate electrode GE in the thickness direction. The capacitor electrode CPE and the gate electrode GE may form a capacitance.

In an embodiment, the second interlayer insulation layer ILD2 may cover the capacitor electrode CPE and the first interlayer insulation layer ILD1. The second interlayer insulation layer ILD2 may include contact holes through which the first connection electrodes CNE1 pass. The contact holes of the second interlayer insulation layer ILD2 may be connected to the contact holes of the first interlayer insulation layer ILD1 and the contact holes of the gate insulation layer GI.

In an embodiment, the first connection electrodes CNE1 may be disposed on the second interlayer insulation layer ILD2. The first connection electrodes CNE1 may electrically connect the drain electrodes DE of the TFTs TFT and the second connection electrodes CNE2. The first connection electrodes CNE1 may be inserted into the contact holes formed in the second interlayer insulation layer ILD2, the first interlayer insulation layer ILD1, and the gate insulation layer GI and may contact the drain electrodes DE of the TFTs TFT.

In an embodiment, the first passivation layer PAS1 may cover the first connection electrodes CNE1 and the second interlayer insulation layer ILD2. The first passivation layer PAS1 may protect the TFTs TFT and may include contact holes through which the second connection electrodes CNE2 pass.

In an embodiment, the second connection electrodes CNE2 may be disposed on the first passivation layer PAS1 and may electrically connect the first connection electrodes CNE1 and pixel electrodes AE of the light-emitting elements ED. The second connection electrodes CNE2 may be inserted into the contact holes formed in the first passivation layer PAS1 and may contact the first connection electrodes CNE1.

In an embodiment, the second passivation layer PAS2 may cover the second connection electrodes CNE2 and the first passivation layer PAS1 and may include contact holes through which the pixel electrodes AE of the light-emitting elements ED pass.

In an embodiment, the light-emitting element layer EML may be disposed on the TFT layer TFTL and may include the light-emitting elements ED and the pixel defining layer PDL. The light-emitting elements ED may include pixel electrodes AE, the light-emitting layer EL, and a common electrode CO.

In an embodiment, the pixel electrodes AE may be disposed on the second passivation layer PAS2, where the pixel electrode AE may be disposed to overlap with any one of the apertures OPE1, OPE2, and OPE3 of the pixel defining layer PDL. The pixel electrodes AE may be electrically connected to the drain electrodes DE of the TFTs TFT through the first connection electrodes CNE1 and the second connection electrodes CNE2.

In an embodiment, the light-emitting layer EL may be disposed on the pixel electrodes AE. For example, the light-emitting layer EL may be an organic light-emitting layer composed of an organic material, but the invention is not limited thereto. When the light-emitting layer EL is an organic light-emitting layer, the TFTs TFT apply a predetermined voltage to the pixel electrodes AE of the light-emitting elements ED, and the common electrode CO of the light-emitting elements ED receives a common voltage or a cathode voltage. Then, holes and electrons move into the light-emitting layer EL through the hole transport layer and the electron transport layer, respectively, and recombine in the light-emitting layer EL to emit light.

In an embodiment, the common electrode CO may be disposed on the light-emitting layer EL. For example, the common electrode CO may be implemented as a common electrode shared by all the pixels, without being divided for each pixel. The common electrode CO may be disposed on the light-emitting layer EL in the emission areas EA1, EA2, and EA3 and may be disposed on the pixel defining layer PDL in areas other than the emission areas EA1, EA2, and EA3.

In an embodiment, the common electrode CO may receive a common voltage or a low-potential voltage. When the pixel electrodes AE receive a voltage corresponding to a data voltage and the common electrode CO receives a low-potential voltage, a potential difference is formed between the pixel electrodes AE and the common electrode CO, allowing light to be emitted from the light-emitting layer EL.

In an embodiment, the pixel defining layer PDL may be disposed on the second passivation layer PAS2 and portions of the pixel electrodes AE and may include a plurality of apertures (OPE1, OPE2, and OPE3). The pixel defining layer PDL may include apertures OPE1, OPE2, and OPE3, and the apertures OPE1, OPE2, and OPE3 may expose portions of the respective pixel electrodes AE. As described above, the apertures OPE1, OPE2, and OPE3 of the pixel defining layer PDL may define the emission areas EA1, EA2, and EA3 and a non-emission area NEA. The areas or sizes of the apertures OPE1, OPE2, and OPE3 of the pixel defining layer PDL may differ from each other. The pixel defining layer PDL may isolate and insulate the pixel electrodes AE of the light-emitting elements ED.

In an embodiment, the pixel defining layer PDL may include a light-absorbing material to prevent light reflection. For example, the pixel defining layer PDL may include a PI binder and a mixture of red, green, and blue pigments. In another embodiment, the pixel defining layer PDL may include a cardo binder resin and a mixture of lactam black pigment and blue pigment. Yet in another embodiment, the pixel defining layer PDL may include carbon black.

In an embodiment, a spacer SPC may be disposed on the pixel defining layer PDL, where the spacer SPC may function to prevent the underlying layers from being damaged during the deposition of the light-emitting layer EL when a mask contacts the layer. The spacer SPC may be directly disposed on the pixel defining layer PDL and may overlap with the non-emission area NEA. The spacer SPC may include an organic material and may be formed to have a thickness of about 1 μm or more.

In an embodiment, the encapsulation layer TFEL may be disposed on the common electrode CO and may cover the light-emitting elements ED. The encapsulation layer TFEL may include at least one inorganic film and may prevent the penetration of oxygen or moisture into the light-emitting element layer EML. The encapsulation layer TFEL may include at least one organic film to protect the light-emitting element layer EML from foreign substances such as dust.

In an embodiment, the encapsulation layer TFEL may include a first encapsulation layer TFE1, a second encapsulation layer TFE2, and a third encapsulation layer TFE3. The encapsulation layers TFE1 and TFE3 may be inorganic encapsulation layers, and the second encapsulation layer TFE2, which is disposed between the encapsulation layers TFEL and TFE3, may be an organic encapsulation layer.

In an embodiment, the encapsulation layers TFE1 and TFE3 may each include one or more inorganic insulating materials. The inorganic insulating materials may include aluminum oxide, titanium oxide, tantalum oxide, hafnium oxide, zinc oxide, silicon oxide, silicon nitride, and/or silicon oxynitride.

In an embodiment, the second encapsulation layer TFE2 may include an organic insulating material. The organic insulating materials may include, for example, an acrylic resin, an epoxy resin, PI, or polyethylene. The second encapsulation layer TFE2 may be formed by curing a monomer or by applying a polymer.

In an embodiment, the touch sensing layer TSU may be disposed on the encapsulation layer TFEL. The touch sensing layer TSU may include a first touch insulating layer TNS1, a second touch insulating layer TNS2, driving electrodes TE, and bridge electrodes CE. Although not illustrated, the touch sensing layer TSU may further include the sensing electrodes RE illustrated in FIG. 7.

In an embodiment, the bridge electrodes CE may be disposed on the third encapsulation layer TFE3 and may be disposed in the non-emission area NEA. For example, the bridge electrodes CE may overlap with the non-emission area NEA. The bridge electrodes CE may be disposed so as not to overlap with the emission areas EA1, EA2, and EA3.

In an embodiment, the first touch insulating layer TNS1 may be disposed on the bridge electrodes CE and the third encapsulation layer TFE3. The first touch insulating layer TNS1 may include an organic film or an inorganic film. For example, the first touch insulating layer TNS1 may include an organic film such as an acrylic resin, an epoxy resin, PI, or polyethylene, or may include an inorganic film such as silicon nitride, silicon oxide, or silicon oxynitride.

In an embodiment, the driving electrodes TE may be disposed directly on the first touch insulating layer TNS1. The driving electrodes TE may be disposed in the non-emission area NEA. For example, the driving electrodes TE may overlap with the non-emission area NEA. The driving electrodes TE may be disposed so as not to overlap with the emission areas EA1, EA2, and EA3. The driving electrodes TE may be connected to the bridge electrodes CE through contact holes penetrating the first touch insulating layer TNS1. Although not illustrated, in an embodiment, the sensing electrodes RE of FIG. 7, which are spaced apart from the driving electrodes TE, may be disposed on the first touch insulating layer TNS1.

In an embodiment, the driving electrodes TE may be formed as single layers of Mo, Ti, Cu, Al, or indium tin oxide (ITO), or as laminated structures of Al and Ti (e.g., Ti/Al/Ti), Al and ITO (e.g., ITO/Al/ITO), a silver (Ag)-palladium (Pd)-copper (Cu) (APC) alloy, or an APC alloy and ITO (e.g., ITO/APC/ITO).

In an embodiment, the second touch insulating layer TNS2 may be disposed on the driving electrodes TE and the first touch insulating layer TNS1. The second touch insulating layer TNS2 may cover the driving electrodes TE and the first touch insulating layer TNS1, flattening any underlying steps. The second touch insulating layer TNS2 may include any one of the aforementioned materials for forming the first touch insulating layer TNS1.

In an embodiment, a scattering layer SL may be disposed on the touch sensing layer TSU. The scattering layer SL may be disposed to correspond to the emission areas EA1 and EA3. For example, the scattering layer SL may overlap with the emission areas EA1 and EA3 but may not overlap with the second emission area EA2. That is, the scattering layer SL may not be disposed in the second emission area EA2. The scattering layer SL may scatter light to prevent diffraction patterns from becoming visible due to red and green light emitted from the emission areas EA1 and EA3. Since blue light emitted from the second emission area EA2 does not interfere with or has a negligible effect on diffraction patterns, the scattering layer SL may not be disposed in the second emission area EA2 to prevent a decrease in transmittance.

In an embodiment, the scattering layer SL may include a scattering resin LR and scattering particles LCP dispersed within the scattering resin LR. The scattering resin LR may include a transparent resin, for example, an acrylic resin. The scattering particles LCP may have a size of about 1 μm or less.

In an embodiment, the color filter layer CFL may be disposed on the touch sensing layer TSU and the scattering layer SL. The color filter layer CFL may include a first color filter 350, a second color filter 360, and a third color filter 370. The color filter layer CFL may also include a first color pattern 355, a second color pattern 365, and a third color pattern 375.

In an embodiment, the first color filter 350 may be disposed on the scattering layer SL and may overlap with the first emission area EA1, where the first color pattern 355 may be spaced apart from the first color filter 350 and may overlap with the non-emission area NEA. The first color filter 350 and the first color pattern 355 may be in direct contact with the scattering layer SL.

In an embodiment, the first color filter 350 and the first color pattern 355 may selectively transmit first light (e.g., red light) and block or absorb second light (e.g., blue light) and third light (e.g., green light). In an embodiment, the first color filter 350 may be a red color filter and may include a red colorant such as a red dye or a red pigment. In this specification, the term “colorant” encompasses both a dye and pigment.

In an embodiment, the second color filter 360 may overlap with the third emission area EA3. In an embodiment, one side of the second color filter 360 may overlap with the non-emission area NEA and may overlap with the adjacent first color filter 350. The other side of the second color filter 360 may overlap with the non-emission area NEA and may overlap with the first color pattern 355. The second color pattern 365 may be spaced apart from the second color filter 360 and may overlap with the non-emission area NEA. The second color pattern 365 may overlap with the first color filter 350 in the non-emission area NEA.

In an embodiment, the second color filter 360 and the second color pattern 365 may selectively transmit the third light (e.g., green light) and block or absorb the first light (e.g., red light) and the second light (e.g., blue light). For example, the second color filter 360 may be a green color filter and may include a green colorant such as a green dye or green pigment.

In an embodiment, the third color filter 370 may overlap with the second emission area EA2, where the third color pattern 375 may be spaced apart from the third color filter 370 and may overlap with the non-emission area NEA. The third color pattern 375 may overlap with the first color filter 350 and the second color filter 360 in the non-emission area NEA.

In an embodiment, the third color filter 370 may selectively transmit the second light (e.g., blue light) and block or absorb the first light (e.g., red light) and the third light (e.g., green light). For example, the third color filter 370 may be a blue color filter and may include a blue colorant such as a blue dye or blue pigment.

In an embodiment, in the non-emission area NEA, the color filters 350, 360, and 370 and the color patterns 355, 365, and 375 may overlap with one another and may thereby block or absorb light. For example, in the portion of the non-emission area NEA located on a first side of the third emission area EA3, the first color filter 350, the second color filter 360, and the third color pattern 375 may overlap, and in the portion of the non-emission area NEA located on a second side of the second emission area EA2, the first color pattern 355, the second color filter 360, and the third color pattern 375 may overlap.

In an embodiment, the overcoat layer OC may be disposed on the color filter layer CFL. The overcoat layer OC may flatten any underlying steps by covering the color filter layer CFL. Additionally, the overcoat layer OC may protect the underlying laminated structure, such as the light-emitting element layer EML. For example, the overcoat layer OC may have high-strength characteristics and may have a modulus of about 3 GPa or more. The modulus of the overcoat layer OC may range from about 3 GPa to about 60 GPa.

In an embodiment, the overcoat layer OC may include a moisture-absorbing agent AML to prevent moisture penetrating from the outside from reaching the color filter layer CFL.

In an embodiment, the overcoat layer OC may include a base resin BR and a moisture-absorbing agent AML dispersed within the base resin BR.

In an embodiment, the base resin BR may include a material that imparts high hardness characteristics to the overcoat layer OC. In an embodiment, the base resin BR may include a polyhedral oligomeric silsesquioxane (POSS)-based organic-inorganic composite material. Specifically, the base resin BR may have at least one of Chemical Formulas A, B, D, and E shown immediately below:

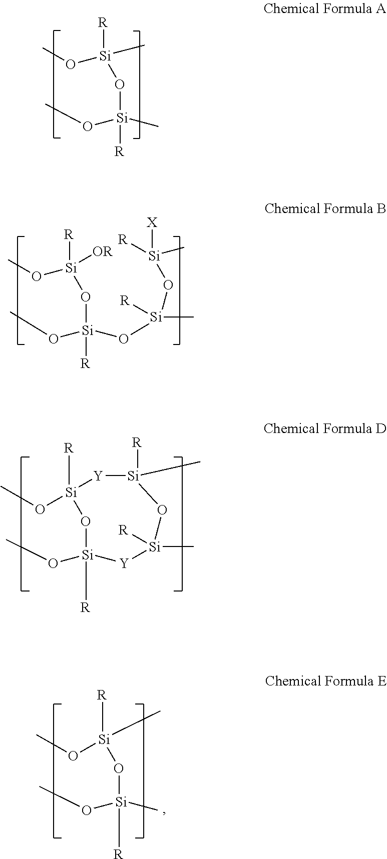

where in Chemical Formula B or D, X and Y are each independently R or [(SiO_{3/2}R)₄₊₂ₙO] (where n is 1 to 10), and R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms. Here, the phenyl group may be either substituted with a substituent or unsubstituted, where the substituent may be selected from hydrogen, deuterium, halogen, an amino group, an epoxy group, a cyclohexyl epoxy group, an acryl group, a methacryl group, a thiol group, an isocyanate group, a nitrile group, or a nitro group.

For example, in an embodiment, the base resin BR may include one or more compounds selected from Chemical Formulas 1 through 14 immediately below:

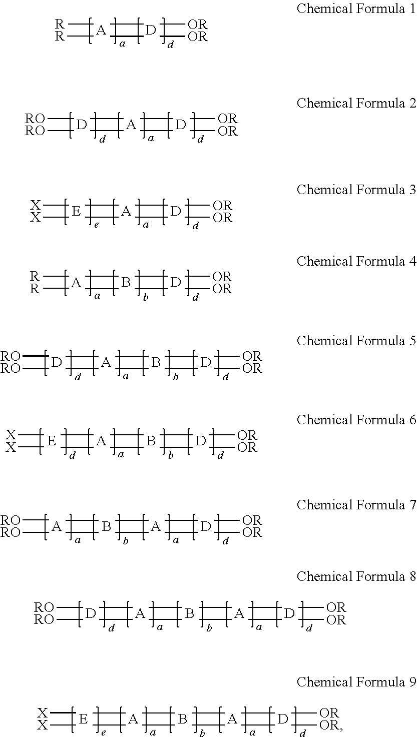

where in Chemical Formulas 1 through 9, R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms. Here, the phenyl group may be either substituted with a substituent or unsubstituted, and the substituent may be independently selected from hydrogen, deuterium, halogen, an amino group, an epoxy group, a cyclohexyl epoxy group, an acryl group, a methacryl group, a thiol group, an isocyanate group, a nitrile group, and a nitro group. X is independently selected from R or [(SiO_{3/2}R)₄₊₂ₙO] (where n is 1 to 10). Furthermore, a, b, d, and e are integers from 1 to 1000.

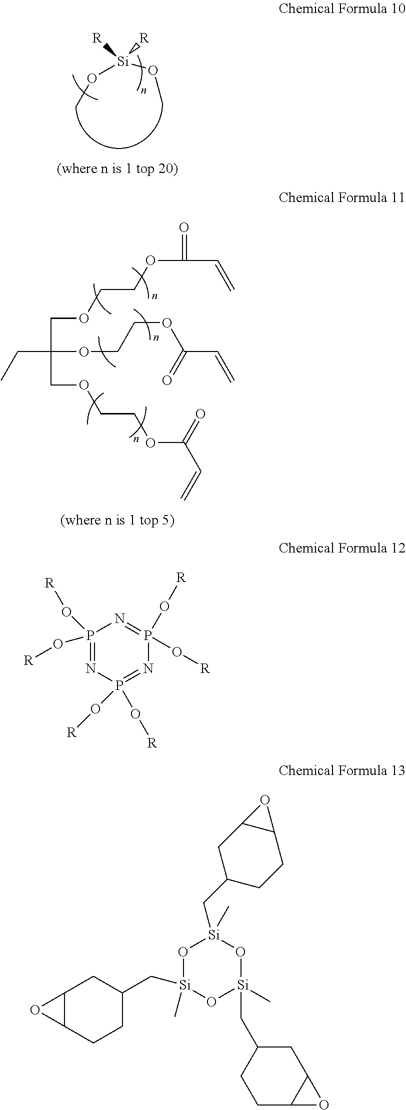

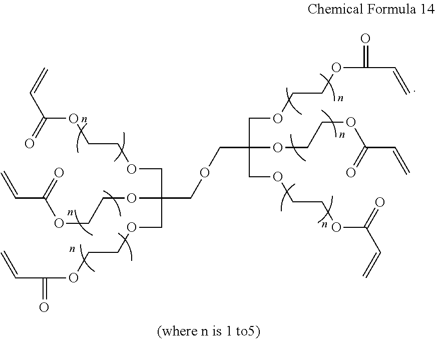

In an embodiment, in Chemical Formulas 10 and 12. R is selected from

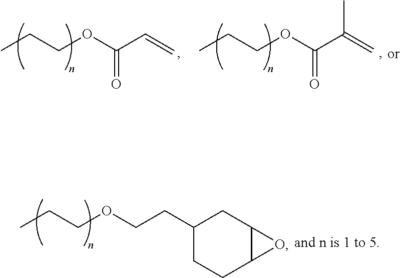

In an embodiment, the moisture-absorbing agent AML is a substance that absorbs moisture and may include an inorganic or organic moisture-absorbing agent. Examples of the inorganic moisture-absorbing agent include at least one selected from zeolite, porous silica, metal-organic frameworks (MOFs), alumina particles, nano clay, porous carbon, calcium chloride (CaCl₂), sodium chloride (NaCl), or bentonite clay. Examples of the organic moisture-absorbing agent include at least one selected from a hemicellulose resin, pectin, silica gel, or starch particles.

In an embodiment, the moisture-absorbing agent AML may be included in particle form, and the particle size of the moisture-absorbing agent AML may range from about 10 nm to about 100 nm. If the particle size of the moisture-absorbing agent AML is about 10 nm or more, the moisture-absorbing properties of the moisture-absorbing agent AML may be enhanced, and if the particle size of the moisture-absorbing agent AML is about 100 nm or less, a decrease in the transmittance of the overcoat layer OC and an increase in haze in the overcoat layer OC may be prevented.

In an embodiment, the content of the moisture-absorbing agent AML may range from about 1 wt % to about 30 wt % relative to the total composition of the overcoat layer OC. If the content of the moisture-absorbing agent AML is about 1 wt % or more, the moisture-absorbing properties of the moisture-absorbing agent AML may be improved, and if the content of the moisture-absorbing agent AML is about 30 wt % or less, a decrease in the transmittance of the overcoat layer OC and an increase in haze in the overcoat layer OC may be prevented.

In an embodiment, the overcoat layer OC may include an initiator that induces a curing reaction under light in the wavelength range of about 300 nm to about 400 nm. For example, the overcoat layer OC may include an ultraviolet (UV) light initiator.

In an embodiment, the thickness of the overcoat layer OC may range from about 3 μm to about 30 μm. If the thickness of the overcoat layer OC is about 3 μm or more, the overcoat layer OC may flatten the underlying steps in the color filter layer CFL, facilitating adhesion of the optical layer OPT. If the thickness of the overcoat layer OC is about 30 μm or less, the overcoat layer OC may prevent deformation of the display device 10 due to stress on the overcoat layer OC.

In an embodiment, an overcoat layer OC with high hardness and moisture-absorbing properties may be formed as a replacement for a cover substrate, thereby preventing a reduction in the reliability of the display device 10. For example, an overcoat layer OC with a modulus of about 3 GPa or more may protect the display device 10 from external impact, and the moisture-absorbing agent AML in the overcoat layer OC may prevent defects in the color filter layer CFL caused by moisture penetration from the outside.

In an embodiment, an adhesive layer ADL may be disposed on the overcoat layer OC, where the adhesive layer ADL may bond the optical layer OPT to the overcoat layer OC.

In an embodiment, the optical layer OPT may be disposed on the adhesive layer ADL, where the optical layer OPT may be bonded through the adhesive layer ADL in film form.

The results of a reliability test for the inclusion of a moisture-absorbing agent in an overcoat layer will hereinafter be described. For this reliability test, in an embodiment, display panels with the structure illustrated in FIG. 9 were prepared and includes a display panel according to a comparative example with no moisture-absorbing agent disposed in the overcoat layer and a display panel, according to an embodiment, with the moisture-absorbing agent. The reliability test was conducted by leaving these display panels in a high temperature and high humidity environment (about 85° C., about 85%) for about 1,000 hours.

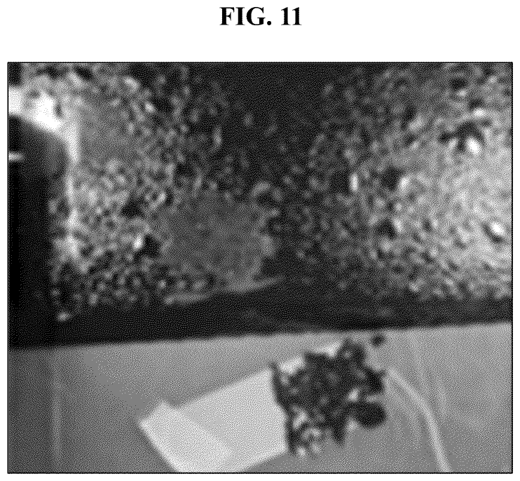

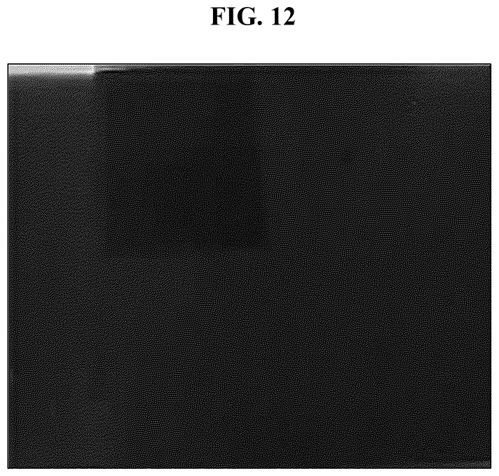

FIG. 11 is an image of the display panel, according to the comparative example. FIG. 12 is an image of the display panel, according to an embodiment.

In an embodiment and referring to FIG. 11, it was observed that the surface of the display panel according to the comparative example exhibited defects, as the surface bulged.

In contrast and in accordance with an embodiment, FIG. 12 shows that no abnormalities were observed on the surface of the display panel.

These results confirm that the display panel, according to an embodiment, by including the moisture-absorbing agent in the overcoat layer, can prevent defects from occurring in the reliability test under high temperature and humidity conditions.

In concluding the detailed description, those skilled in the art will appreciate that many variations and modifications can be made to the invention without substantially departing from the principles of the invention. Therefore, the disclosed embodiments are used in a generic and descriptive sense only and not for purposes of limitation.

What is claimed is:

1. A display device comprising:
a substrate;
a light-emitting element layer disposed on the substrate and emitting light;
an encapsulation layer disposed on the light-emitting element layer;
a touch sensing layer disposed on the encapsulation layer;
a color filter layer disposed on the touch sensing layer; and
an overcoat layer disposed on the color filter layer,
wherein the overcoat layer includes a base resin and a moisture-absorbing agent dispersed in the base resin.

2. The display device of claim 1, wherein a modulus of the overcoat layer is in a range of about 3 GPa to about 60 GPa.

3. The display device of claim 1, wherein
the base resin includes at least one of Chemical Formulas A, B, D, and E: 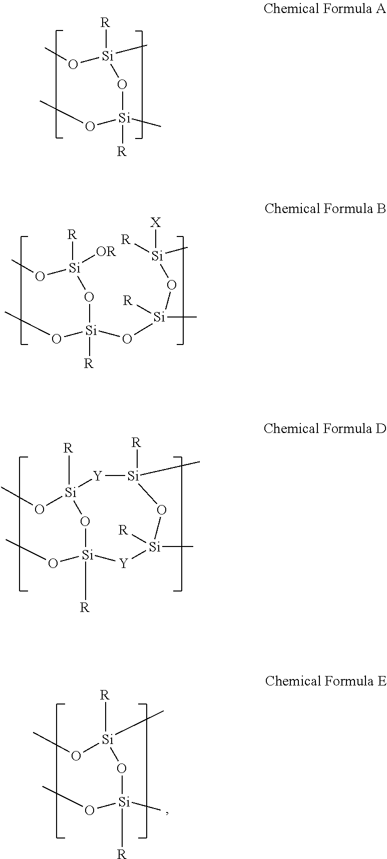
and
wherein in Chemical Formula B or D, X and Y are each independently R or [(SiO_{3/2}R)₄₊₂ₙO] (where n is 1 to 10), and
wherein R is independently selected from at least one of hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms; and
wherein the phenyl group is either unsubstituted or substituted with a substituent, wherein the substituent is selected from at least one of hydrogen, deuterium, halogen, an amino group, an epoxy group, a cyclohexyl epoxy group, an acryl group, a methacryl group, a thiol group, an isocyanate group, a nitrile group, or a nitro group.

4. The display device of claim 3, wherein
the base resin includes at least one compound selected from Chemical Formulas 1 through 14, wherein Chemical Formulas 1 through 9 are as follows: 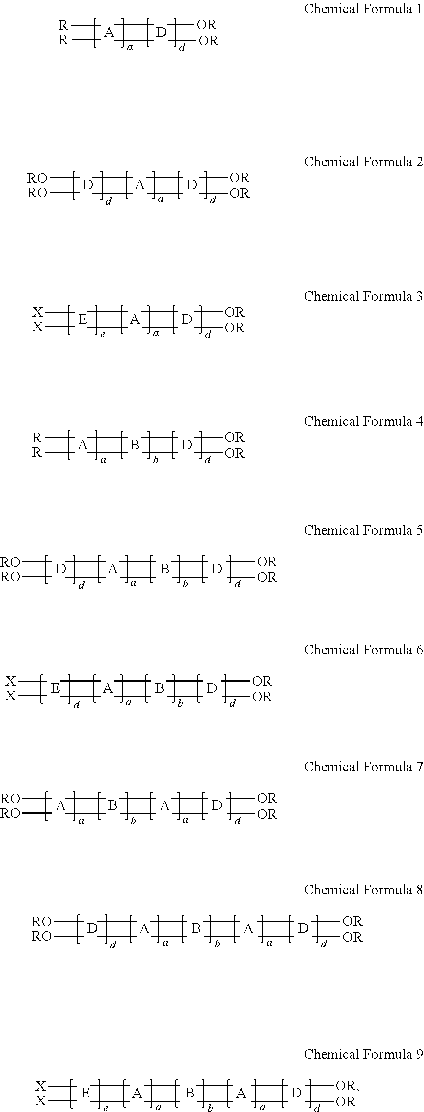
where in Chemical Formulas 1 through 9, R is independently selected from at least one of hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms;
the phenyl group is either unsubstituted or substituted with a substituent, where the substituent is independently selected from at least one of hydrogen, deuterium, halogen, an amino group, an epoxy group, a cyclohexyl epoxy group, an acryl group, a methacryl group, a thiol group, an isocyanate group, a nitrile group, and a nitro group;
wherein X is independently selected from R or [(SiO_{3/2}R)₄₊₂ₙO] (where n is 1 to 10); and
a, b, d, and e are integers from 1 to 1000, and
where Chemical Formulas 10 through 14 are as follows: 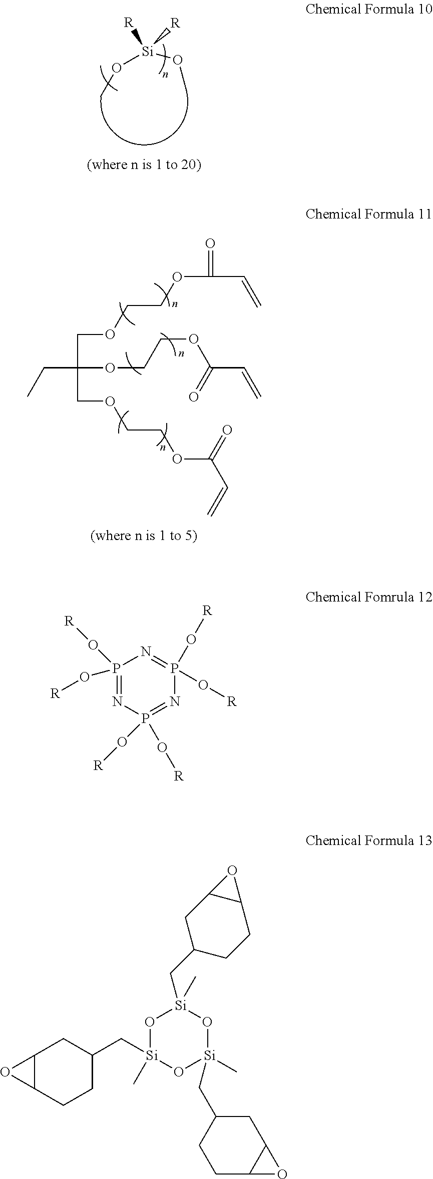 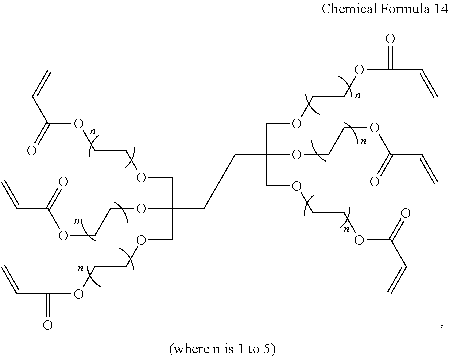
and
where in Chemical Formulas 10 and 12, R is selected from

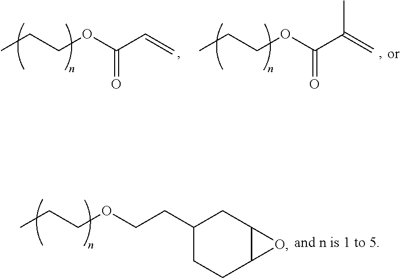

5. The display device of claim 1, wherein the moisture-absorbing agent includes at least one inorganic moisture-absorbing agent selected from zeolite, porous silica, metal-organic frameworks (MOFs), alumina particles, nano clay, porous carbon, calcium chloride (CaCl₂), sodium chloride (NaCl), or bentonite clay.

6. The display device of claim 1, wherein the moisture-absorbing agent includes at least one organic moisture-absorbing agent selected from a hemicellulose resin, pectin, silica gel, or starch particles.

7. The display device of claim 1, wherein
the moisture-absorbing agent is included in particle form, and
a particle size of the moisture-absorbing agent is in a range from about 10 nm to about 100 nm.

8. The display device of claim 1, wherein a content of the moisture-absorbing agent is in a range from about 1 wt % to about 30 wt % relative to a total composition of the overcoat layer.

9. The display device of claim 1, wherein a thickness of the overcoat layer is in a range from about 3 μm to about 30 μm.

10. A display device comprising:
a substrate;
a light-emitting element layer disposed on the substrate and including a plurality of emission areas;
an encapsulation layer disposed on the light-emitting element layer;
a touch sensing layer disposed on the encapsulation layer;
a scattering layer disposed on the touch sensing layer;
a color filter layer disposed on the scattering layer and the touch sensing layer; and
an overcoat layer disposed on the color filter layer,
wherein the overcoat layer has a modulus in a range of about 3 GPa to about 60 GPa, and includes a base resin and a moisture-absorbing agent dispersed in the base resin.

11. The display device of claim 10, wherein
the emission areas includes a first emission area, a second emission area, and a third emission area, and
the scattering layer overlaps with the first emission area and the third emission area and does not overlap with the second emission area.

12. The display device of claim 11, wherein
the first emission area emits red light,
the second emission area emits blue light, and
the third emission area emits green light.

13. The display device of claim 10, further comprising:
an optical layer in film form bonded onto the overcoat layer.

14. The display device of claim 10, wherein
the base resin includes at least one of Chemical Formulas A, B, D, and E: 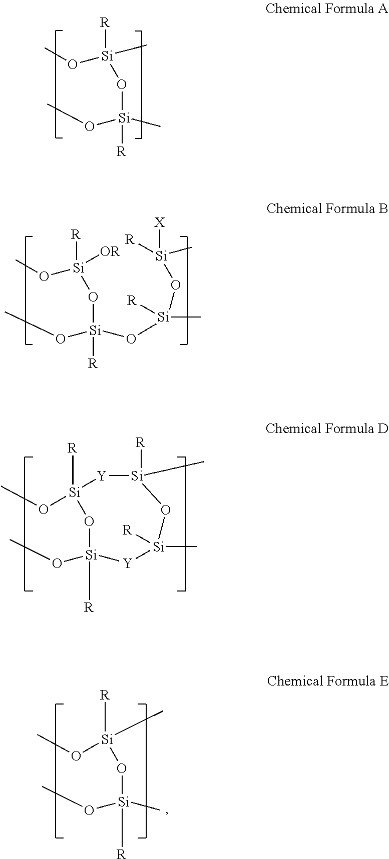
and
where in Chemical Formula B or D, X and Y are each independently R or [(SiO_{3/2}R)₄₊₂ₙO] (where n is 1 to 10), and
where R is independently selected from hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms;
where the phenyl group is either unsubstituted or substituted with a substituent, where the substituent is selected from at least one of hydrogen, deuterium, halogen, an amino group, an epoxy group, a cyclohexyl epoxy group, an acryl group, a methacryl group, a thiol group, an isocyanate group, a nitrile group, or a nitro group.

15. The display device of claim 14, wherein
the base resin includes at least one compound selected from Chemical Formulas 1 through 14, where Chemical Formulas 1 through 9 are as follows: 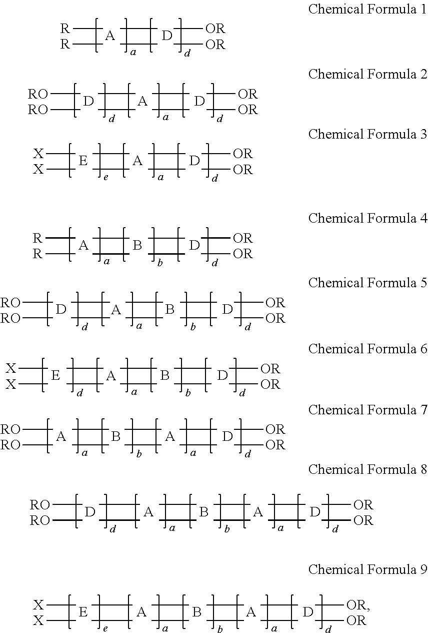
where in Chemical Formulas 1 through 9, R is independently selected from at least one of hydrogen, deuterium, halogen, an amino group, an epoxy group, a cyclohexyl epoxy group, an acryl group, a methacryl group, a thiol group, an isocyanate group, a nitrile group, a nitro group, a phenyl group, an alkyl group with 1 to 12 carbon atoms, an alkenyl group with 2 to 12 carbon atoms, an alkoxy group with 1 to 40 carbon atoms, a cycloalkyl group with 3 to 12 carbon atoms, a heterocycloalkyl group with 3 to 12 carbon atoms, an aryl group with 6 to 12 carbon atoms, a heteroaryl group with 3 to 12 carbon atoms, an aralkyl group with 3 to 12 carbon atoms, an aryloxy group with 3 to 12 carbon atoms, or an arylthiol group with 3 to 12 carbon atoms;
where the phenyl group is either unsubstituted or substituted with a substituent, where the substituent is independently selected from hydrogen, deuterium, halogen, an amino group, an epoxy group, a cyclohexyl epoxy group, an acryl group, a methacryl group, a thiol group, an isocyanate group, a nitrile group, and a nitro group;
where X is independently selected from R or [(SiO_{3/2}R)₄₊₂ₙO] (where n is 1 to 10); and
a, b, d, and e are integers from 1 to 1000, and
where Chemical Formulas 10 through 14 are as follows: 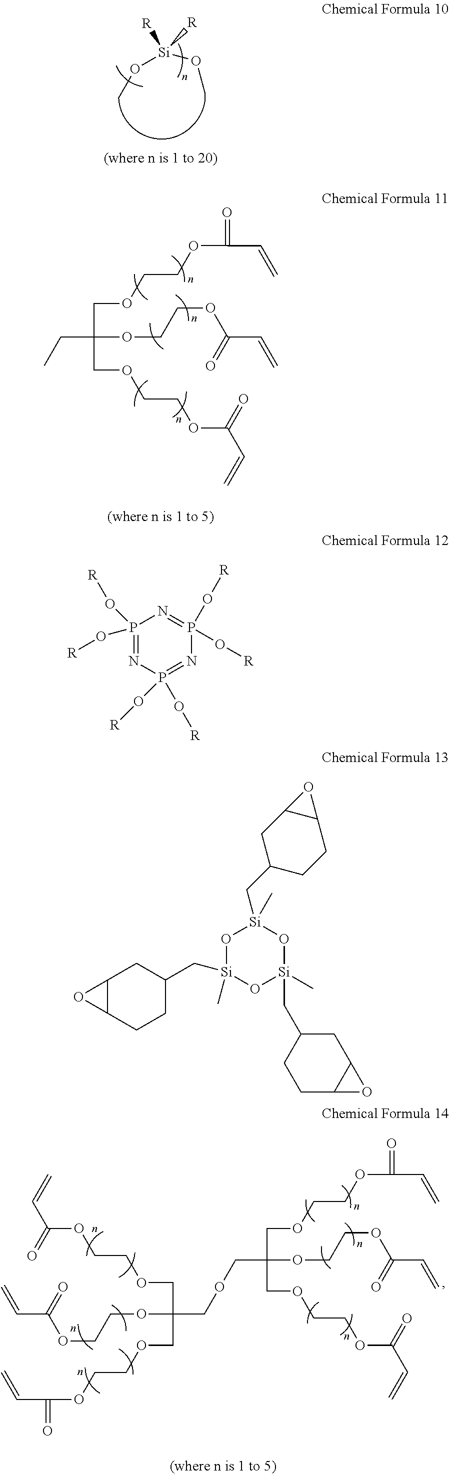
and
Where in Chemical Formulas 10 and 12, R is selected from

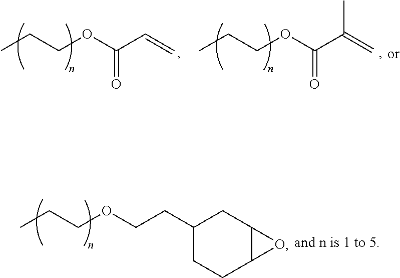

16. The display device of claim 10, wherein the moisture-absorbing agent includes at least one inorganic moisture-absorbing agent selected from zeolite, porous silica, metal-organic frameworks (MOFs), alumina particles, nano clay, porous carbon, calcium chloride (CaCl₂), sodium chloride (NaCl), or bentonite clay.

17. The display device of claim 10, wherein the moisture-absorbing agent includes at least one organic moisture-absorbing agent selected from a hemicellulose resin, pectin, silica gel, or starch particles.

18. The display device of claim 10, wherein
the moisture-absorbing agent is included in particle form, and
a particle size of the moisture-absorbing agent is in a range from about 10 nm to about 100 nm.

19. The display device of claim 10, wherein a content of the moisture-absorbing agent is in a range from about 1 wt % to about 30 wt % relative to a total composition of the overcoat layer.

20. The display device of claim 10, wherein a thickness of the overcoat layer is in a range from about 3 μm to about 30 μm.
